(19) United States
(12) Patent Application Publication
(10) Pub. No.: US 2025/0087502 A1
(43) Pub. Date: Mar. 13, 2025

(54) SEMICONDUCTOR MANUFACTURING APPARATUS AND METHOD FOR MANUFACTURING SEMICONDUCTOR DEVICE

(71) Applicant: Kioxia Corporation, Tokyo (JP)

(72) Inventors: Kohei YUKI, Yokkaichi (JP); Kazuhiro NOJIMA, Mie (JP); Keiichi NIWA, Yokkaichi (JP); Takanobu ONO, Kuwana (JP)

(73) Assignee: Kioxia Corporation, Tokyo (JP)

(21) Appl. No.: 18/806,049

(22) Filed: Aug. 15, 2024

(30) Foreign Application Priority Data
Sep. 8, 2023 (JP) 2023-146383

(51) Int. Cl. H01L 21/67; H01L 21/677; H01L 21/78

(52) U.S. Cl. CPC H01L 21/67092; H01L 21/67288; H01L 21/67769; H01L 21/78

(57) ABSTRACT

A semiconductor manufacturing apparatus includes a storage device configured to store first location information of a plurality of first lines on a first surface of a semiconductor wafer to be cut, and further store second location information of a second line not to be cut among the plurality of first lines; and a cutter configured to cut the semiconductor wafer along one or more of the plurality of first lines other than the second line. The semiconductor wafer is configured to be cut into a plurality of semiconductor chips.

### CROSS-REFERENCE TO RELATED APPLICATION(S)

This application is based upon and claims the benefit of priority from Japanese Patent Application No. 2023-146383, filed Sep. 8, 2023, the entire contents of which are incorporated herein by reference.

### FIELD

Embodiments described herein relate generally to a semiconductor manufacturing apparatus and a method for manufacturing a semiconductor device.

### BACKGROUND

A void may be generated at a bonding interface of a bonding wafer including a plurality of semiconductor wafers bonded to one another. Such a void can cause the semiconductor wafer to be chipped, for example, in the dicing step of the bonding wafer. The chipping of the semiconductor wafer may contaminate a dicing device, and may make it difficult to process the bonding wafer and the semiconductor chip in the subsequent step.

### DESCRIPTION OF THE DRAWINGS

FIG. 1 is a block diagram showing a configuration example of a dicing device according to a first embodiment.

FIG. 2 is a cross-sectional view showing an example of a defect of a semiconductor wafer.

FIG. 3 is a flowchart showing an example of a dicing method using the dicing device according to the first embodiment.

FIG. 4 is a conceptual plan view of the semiconductor wafer showing an example of the dicing method.

FIG. 5 is a plan view showing an example of the dicing method following FIG. 4.

FIG. 6 is a plan view showing an example of the dicing method following FIG. 5.

FIG. 7 is a plan view showing an example of the dicing method following FIG. 6.

FIG. 8 is a table showing location information of a dicing region.

FIG. 9 is a table showing location information of the dicing region.

FIG. 10 is a plan view showing a semiconductor chip that is not divided into individual pieces.

FIG. 11 is a table showing an example of location information of a dicing line surrounding the semiconductor chip that is not divided into individual pieces.

FIG. 12 is a table showing an example of location information of a dicing line surrounding the semiconductor chip that is not divided into individual pieces.

### DETAILED DESCRIPTION

In general, according to one embodiment, a semiconductor manufacturing apparatus includes a storage device configured to store first location information of a plurality of first lines on a first surface of a semiconductor wafer to be cut, and further store second location information of a second line not to be cut among the plurality of first lines; and a cutter configured to cut the semiconductor wafer along one or more of the plurality of first lines other than the second line. The semiconductor wafer is configured to be cut into a plurality of semiconductor chips.

Hereinafter, embodiments of the present disclosure will be described with reference to the drawings. The present embodiment does not limit the present disclosure. The drawings are schematic or conceptual. In the specification and drawings, the same elements are denoted by the same reference numerals.

### First Embodiment

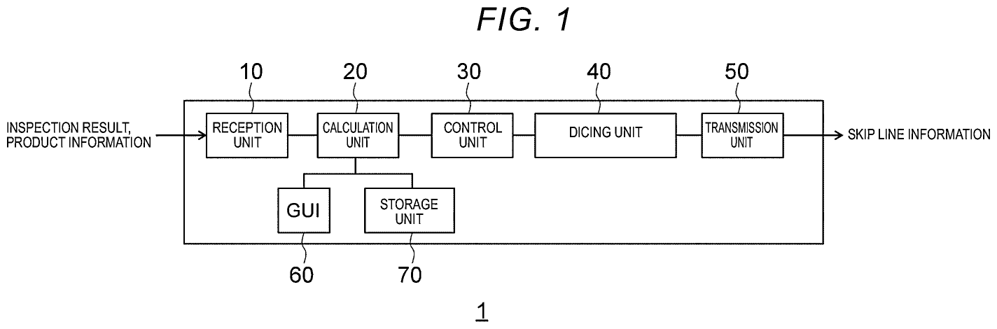

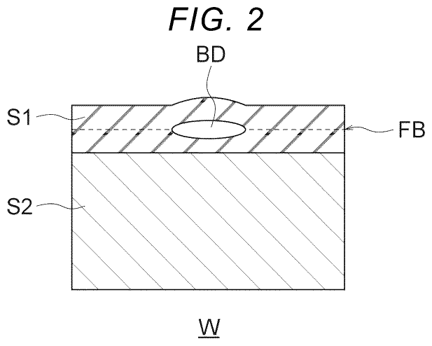

FIG. 1 is a block diagram showing a configuration example of a dicing device according to a first embodiment. A dicing device 1 is a semiconductor manufacturing apparatus that cuts a semiconductor wafer into a plurality of semiconductor chips. The semiconductor wafer may be configured with, for example, a single semiconductor substrate, or may be configured with a bonding wafer in which a plurality of semiconductor substrates S1 and S2 are bonded together as shown in FIG. 2. A semiconductor element is already formed on a surface of the semiconductor wafer in a previous step of a semiconductor manufacturing step. After the previous step, the semiconductor wafer is subjected to a surface inspection, an electrical characteristic inspection, and the like, and is divided into individual pieces of the semiconductor chips by the dicing device 1.

The dicing device 1 includes a reception unit (or receiver) 10, a calculation unit (or calculator) 20, a control unit (or controller) 30, a dicing unit (or cutter) 40, a transmission unit (or transmitter) 50, a graphical user interface (GUI) 60, and a storage unit (or storage device) 70.

The reception unit 10 receives an inspection result obtained in the surface inspection from the outside. The inspection result is received from an inspection device (not shown). The inspection result is, for example, location information of a defect on a surface of the semiconductor wafer. The defect of the semiconductor wafer is, for example, a void BD generated on a bonding surface FB of the bonding wafer as shown in FIG. 2. The location information may be in a planar coordinate with a center of the semiconductor wafer as an origin.

The void BD may cause the semiconductor chip to be chipped when cut in the dicing step, and may cause contamination in a subsequent back grinding step or the like. Therefore, the dicing device 1 according to the present embodiment is set not to cut the void BD based on the location information of the defect and the like.

The calculation unit 20 sets a skip line that is not cut among the dicing lines of the semiconductor wafer based on the product information of the semiconductor wafer and the location information of the defect. The dicing line is an example of a first line planned to be cut on the surface of the semiconductor wafer. The dicing line is between a plurality of adjacent semiconductor chips. Meanwhile, the skip line is a dicing line that is not to be cut in the dicing step among the dicing lines, and for example, is set in a line portion of the dicing line not to be cut that has a defect such as the void BD. The skip line is an example of a second line. The calculation unit 20 sets whether to set each line segment of a dicing line corresponding to a side of a plurality of adjacent semiconductor chips as a skip line. That is, the skip line is partially set for each side of the semiconductor chip. The calculation unit 20 may be, for example, a central processing unit (CPU) or the like. The setting of the skip line will be described in detail later.

The control unit 30 controls the dicing unit 40. At this time, the control unit 30 controls the dicing unit 40 such that the dicing line that is not set as the skip line among the dicing lines is cut and the dicing line set as the skip line among the dicing lines is not cut. The control unit 30 may be, for example, a CPU, a programmable logic controller (PLC), or the like.

The dicing unit 40 cuts the semiconductor wafer under the control of the control unit 30. The dicing unit 40 cuts the dicing lines other than the skip lines. The dicing unit 40 includes, for example, a dicing blade that cuts the semiconductor wafer by rotating a blade or a laser generator that cuts the semiconductor wafer with laser light. The dicing unit 40 further includes a stage on which the semiconductor wafer is placed, a conveyance mechanism that conveys the semiconductor wafer to and from the stage, and the like (not shown).

The transmission unit 50 transmits the location information of the semiconductor chip adjacent to the skip line to the outside. The reception unit 10 and the transmission unit 50 may be configured as one input/output circuit.

The GUI 60 displays the inspection information of the semiconductor wafer, the product information of the semiconductor wafer, the dicing line, the dicing region, the skip line, and the like on the surface of the semiconductor wafer. Further, the GUI 60 is configured to allow the user to input information. For example, a user selects a product to be diced in the GUI 60. The GUI 60 transfers the selected product information to the calculation unit 20. The calculation unit 20 extracts the product information selected by the user from the plurality of pieces of product information stored in the storage unit 70. The GUI 60 displays product information of the semiconductor wafer to be diced. The GUI 60 may be, for example, a touch panel display, a keyboard, or the like.

The storage unit 70 stores product information of a semiconductor wafer related to various products and an inspection result of each semiconductor wafer received by the reception unit 10 in advance. The product information of the semiconductor wafer is information specified by the product formed on the semiconductor wafer, and includes, for example, size information of a semiconductor chip, location information of a unique pattern provided on the semiconductor chip, interval information between adjacent dicing lines, length information of the dicing line, and the like. The unique pattern may be, for example, an alignment mark provided in each semiconductor chip. The storage unit 70 stores product information of a plurality of products in advance. The calculation unit 20 receives product information corresponding to the product from the storage unit 70 when the user selects a certain product using the GUI 60.

In addition, the storage unit 70 stores the inspection information of the semiconductor wafer received by the reception unit 10 in the dicing step. The inspection information is information unique to each semiconductor wafer, and is stored in the storage unit 70 for each semiconductor wafer. The location information of the defect may be expressed in location coordinates with a center of the surface of the semiconductor wafer as an origin.

The storage unit 70 also stores location information of the skip line set based on the location information of the defect among the dicing lines. Thereby, the dicing unit 40 can cut the dicing lines other than the line portion of the dicing line set as the skip line among the dicing lines.

Further, the storage unit 70 stores a region planned to be removed when the dicing line is cut by the dicing unit 40 as a dicing region. The dicing region is a region having a width to be removed by dicing with a dicing line as a center on the surface of the semiconductor wafer. In other words, the dicing region is a region other than the semiconductor chip cut out from the semiconductor wafer. The storage unit 70 may be, for example, a memory or a storage such as a solid state drive (SSD) or a hard disc drive (HDD).

FIG. 2 is a cross-sectional view showing an example of a defect of a semiconductor wafer. A semiconductor wafer W is, for example, a bonding wafer in which the plurality of semiconductor substrates S1 and S2 are bonded to each other at the bonding surfaces FB. In such the semiconductor wafer W, the void BD may remain as a defect on the bonding surface FB. As described above, cutting the void BD causes the semiconductor chip to be chipped. Therefore, when the defect of the void BD or the like is formed in the dicing line, the calculation unit 20 sets a line portion of the dicing line as a skip line and does not cut the defect.

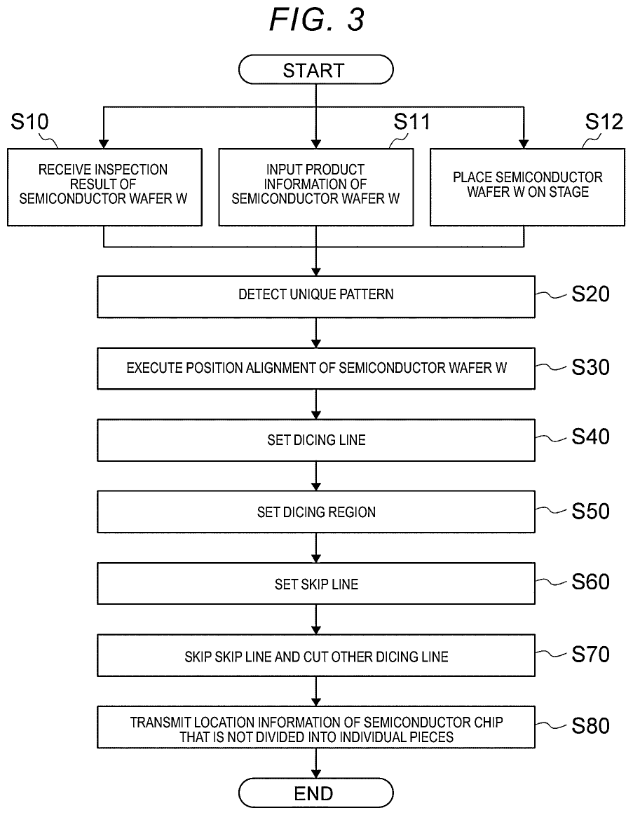

FIG. 3 is a flowchart showing an example of a dicing method using a dicing device according to the first embodiment. FIGS. 4 to 7 are conceptual plan views of the semiconductor wafer showing an example of the dicing method. The storage unit 70 stores product information of a semiconductor wafer related to various products in advance.

First, the reception unit 10 receives an inspection result of the semiconductor wafer W from an external inspection device (not shown) (S10). The inspection result includes location information of a defect (for example, the void BD) on the surface of the semiconductor wafer W. The inspection result is stored in the storage unit 70. Further, the user inputs or selects product information of the semiconductor wafer W to be diced using the GUI 60 (S11). The product information of the semiconductor wafer W to be diced is stored in the storage unit 70. Further, the dicing device 1 conveys the semiconductor wafer W to be diced into a chamber of the dicing unit 40 and places the semiconductor wafer W on a stage (not shown) (S12).

Next, as shown in FIG. 4, the calculation unit 20 detects unique patterns (for example, alignment marks) UP1 to UP3 of the plurality of semiconductor chips in the semiconductor wafer W from the product information (S20). The control unit 30 executes position alignment of the semiconductor wafer W by using the location information of the unique patterns UP1 to UP3 (S30). The position alignment of the semiconductor wafer W is executed in the X direction, the Y direction intersecting the X direction, and the rotation direction in the X-Y plane. At this time, in a plan view of the semiconductor wafer W as viewed from the surface, location information of unique patterns of two or more semiconductor chips is used to reduce a deviation in the rotation direction. For example, as shown in FIG. 4, the position alignment of the semiconductor wafer W may be executed using three unique patterns UP1 to UP3.

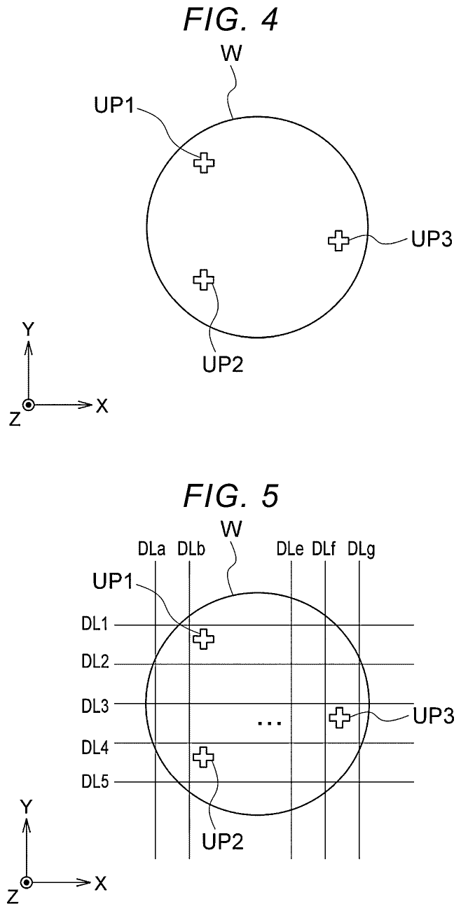

Next, as shown in FIG. 5, the calculation unit 20 sets dicing lines DLa to DLg and DL1 to DL5 on the surface of the semiconductor wafer W based on the interval information between the dicing lines and the length information of the dicing lines (S40). The interval information between the dicing lines indicates, for example, an interval between the plurality of dicing lines DLa to DLg adjacent to each other in the X direction and an interval between the plurality of dicing lines DL1 to DL5 adjacent to each other in the Y direction. In the same semiconductor wafer W, the intervals between the dicing lines DLa to DLg in the X direction may be equal and may have the same pitch. In addition, in the same semiconductor wafer W, the interval between the dicing lines DL1 to DL5 in the Y direction may be equal and may have the same pitch.

The length information of the dicing lines DLa to DLg and DL1 to DL5 may be individually set for each of the plurality of dicing lines DLa to DLg and DL1 to DL5. Alternatively, the lengths of the plurality of dicing lines DLa to DLg and DL1 to DL5 may be equal lengths as shown in FIG. 5. In this case, the lengths of the dicing lines DLa to DLg and DL1 to DL5 are longer than the diameter of the semiconductor wafer W so that the dicing unit 40 is capable of dicing up to the end portion of the semiconductor wafer W.

For example, as shown in FIG. 5, the calculation unit 20 sets the plurality of dicing lines DL1 to DL5 extending in the X direction and the plurality of dicing lines DLa to DLg extending in the Y direction. The dicing lines DL1 to DL5 and the dicing lines DLa to DLg are, for example, substantially orthogonal to each other. The number of the dicing lines DL1 to DL5 and the number of the dicing lines DLa to DLg are not particularly limited, and depend on a chip size of the semiconductor chip.

The location information of the dicing lines DLa to DLg and DL1 to DL5 may be set by a coordinate of one end and a coordinate of the other end. The location information of the dicing lines DLa to DLg and DL1 to DL5 is stored in the storage unit 70. In addition, the intersection coordinates of the dicing lines DLa to DLg and DL1 to DL5 are also stored in the storage unit 70. Thereby, the calculation unit 20 can specify a part of the intersection between the dicing lines DLa to DLg and DL1 to DL5.

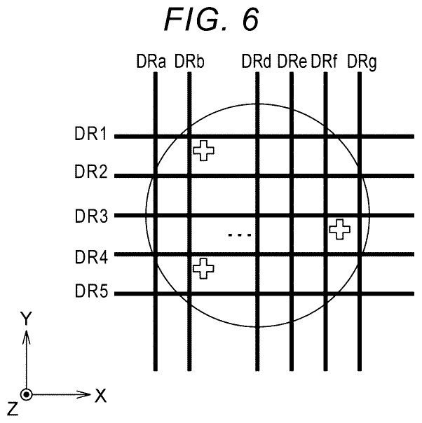

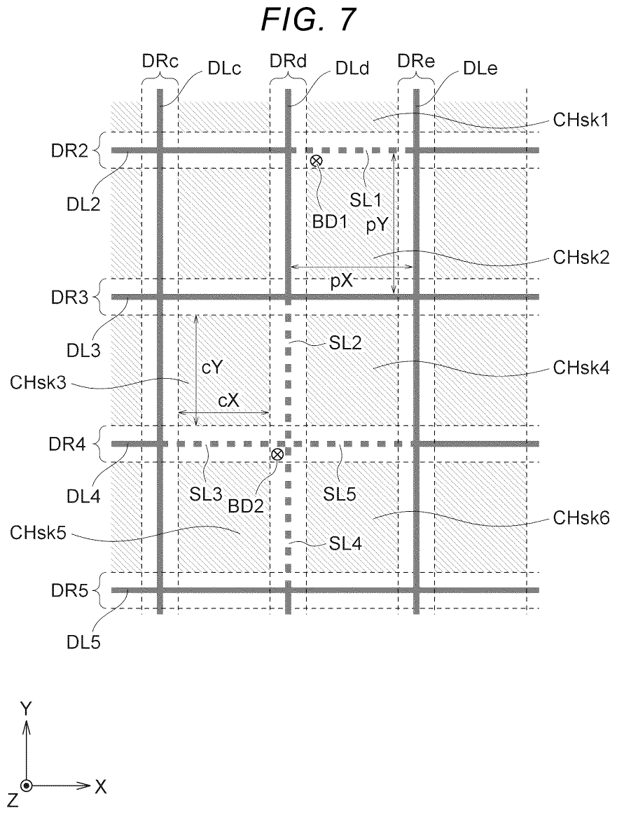

Next, as shown in FIGS. 6 and 7, the calculation unit 20 sets dicing regions DRa to DRg and DR1 to DR5 on the surface of the semiconductor wafer W based on the location information of the dicing lines DLa to DLg and DL1 to DL5, the interval information between the dicing lines DLa to DLg and DL1 to DL5, the length information of the dicing lines DLa to DLg and DL1 to DL5, and the size information of a semiconductor chip CH (S50). The dicing regions DRa to DRg and DR1 to DR5 are regions planned to be removed when the dicing lines DLa to DLg and DL1 to DL5 are cut by the dicing unit 40. Therefore, the region of the semiconductor wafer W other than the dicing regions DRa to DRg and DR1 to DR5 is the region of the semiconductor chip CH. The size information of the semiconductor chip CH is a size of the semiconductor chip CH in an X-Y plane cut out from the semiconductor wafer W.

Here, for example, as shown in FIG. 7, the width of the semiconductor chip CH in the X direction is denoted by cX, and the width of the semiconductor chip CH in the Y direction is denoted by cY. An interval between the dicing lines (second planned cutting lines) DLa to DLg adjacent to each other in the X direction is denoted by pX, and an interval between the dicing lines (first planned cutting lines) DL1 to DL5 adjacent to each other in the Y direction is denoted by pY.

At this time, the calculation unit 20 sets a region having a width of ±(pY−cY)/2 in the Y direction from each of the dicing lines DL1 to DL5 as the dicing regions DR1 to DR5. In addition, the calculation unit 20 sets a region having a width of ±(pX−cX)/2 in the X direction from each of the dicing lines DLa to DLg as the dicing regions DRa to DRg.

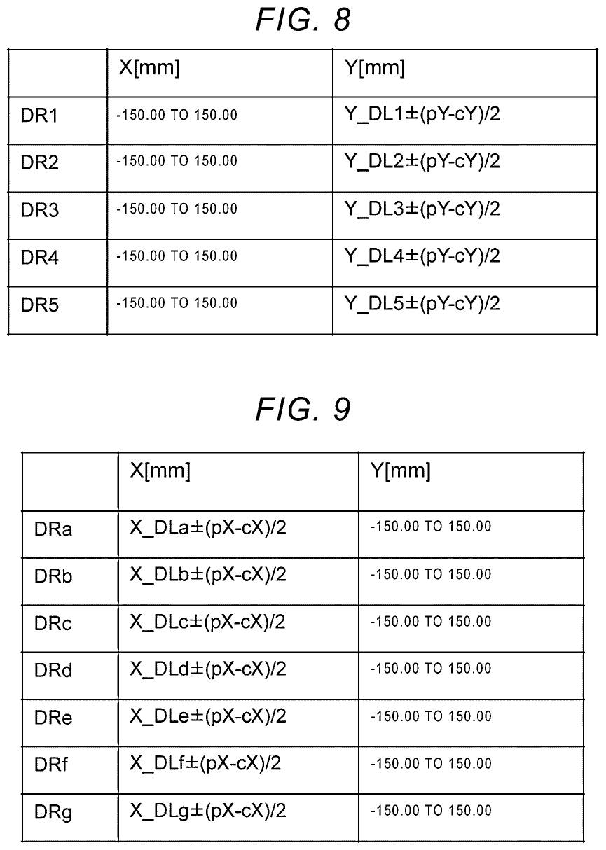

FIG. 8 is a table showing the location information of the dicing regions DR1 to DR5. The X column of the table in FIG. 8 shows the length in the X direction (for example, −150 mm to 150 mm) of the dicing regions DR1 to DR5. The Y column of the table in FIG. 8 shows the width of the dicing regions DR1 to DR5 in the Y direction. Y_DL1 to Y_DL5 indicate Y coordinates of each of the dicing lines DL1 to DL5. Therefore, it can be seen that the dicing regions DR1 to DR5 are regions having a width of ±(pY−cY)/2 in the Y direction with the dicing lines DL1 to DL5 as centers on the surface of the semiconductor wafer W, respectively. In addition, the length in the X direction (for example, −150 mm to 150 mm) of each of the dicing regions DR1 to DR5 may be the same as the length in the X direction of each of the dicing lines DL1 to DL5 and may be equal to or greater than the diameter of the semiconductor wafer W.

FIG. 9 is a table showing the location information of the dicing regions DRa to DRg. The Y column of the table in FIG. 9 shows the length (−150 mm to 150 mm) of the dicing regions DRa to DRg in the Y direction. The X column of the table in FIG. 9 shows the width of the dicing regions DRa to DRg in the X direction. X_DLa to X_DLg indicate X coordinates of each of the dicing lines DLa to DLg. Therefore, it may be understood that the dicing regions DRa to DRg are regions having a width of ±(pX−cX)/2 in the X direction with the dicing lines DLa to DLg as centers on the surface of the semiconductor wafer W. In addition, the length in the Y direction (for example, −150 mm to 150 mm) of each of the dicing regions DRa to DRg may be the same as the length of each of the dicing lines DLa to DLg in the X direction and may be equal to or greater than the diameter of the semiconductor wafer W.

The calculation unit 20 stores the location information of the dicing regions DR1 to DR5 and DRa to DRg set as described above in the storage unit 70.

Next, the calculation unit 20 sets the skip line based on the location information of the defect and the location information of the dicing region (S60). The location information of the defect indicates a coordinate of the defect in a plane of the semiconductor wafer W. For example, as shown in FIG. 7, it is assumed that defects BD1 and BD2 are present. The defect BD1 is present in the dicing region DR2. Therefore, the calculation unit 20 sets a skip line SL in the dicing line DL2 corresponding to the dicing region DR2. More specifically, the calculation unit 20 sets a line segment between a semiconductor chip CHsk1 and a semiconductor chip CHsk2 adjacent to each other in the dicing region DR2 in which the defect BD1 is present as a skip line SL1. The skip line SL1 corresponds to the sides of the adjacent semiconductor chips CHsk1 and CHsk2, and is indicated by a broken line in FIG. 7.

In addition, the defect BD2 is in an overlapping region between the dicing region DR4 and the dicing region DRd. In this case, the calculation unit 20 sets the skip line SL in the dicing lines DL4 and DLd corresponding to the dicing regions DR4 and DRd. The overlapping region in which the defect BD2 is present corresponds to the corner portion of semiconductor chips CHsk3 to CHsk6. Therefore, the calculation unit 20 sets a line segment SL2 between the semiconductor chip CHsk3 and the semiconductor chip CHsk4 adjacent to each other, a line segment SL3 between the semiconductor chip CHsk3 and the semiconductor chip CHsk5, a line segment SL4 between the semiconductor chip CHsk5 and the semiconductor chip CHsk6, and a line segment SL5 between the semiconductor chip CHsk6 and the semiconductor chip CHsk4 in the overlapping region in which the defect BD2 is present, as the skip lines. The skip line SL2 corresponds to one side between the semiconductor chips CHsk3 and CHsk4. The skip line SL3 corresponds to one side between the semiconductor chips CHsk3 and CHsk5. The skip line SL4 corresponds to one side between the semiconductor chips CHsk5 and CHsk6. The skip line SL5 corresponds to one side between the semiconductor chips CHsk6 and CHsk4. The skip lines SL2 to SL5 are indicated by broken lines in FIG. 7.

In this way, in the present embodiment, the calculation unit 20 sets a portion in the dicing lines DL2, DL4, and DLd corresponding to the dicing regions DR2, DR4, and DRd in which the defects BD1 and BD2 are present as the skip lines SL1 to SL5 for each line segment corresponding to the sides of the plurality of adjacent semiconductor chips CHsk1 to CHsk5.

The location information of the skip lines SL1 to SL5 is stored in the storage unit 70. The location information of the skip lines SL1 to SL5 may be location coordinates (intersection coordinates at both ends) of the dicing lines corresponding to the skip lines SL1 to SL5. For example, the location information of the skip line SL1 may be indicated by the intersection coordinates of the dicing lines DL2 and DLd and the intersection coordinates of the dicing lines DL2 and DLe. The location information of the skip line SL2 may be indicated by the intersection coordinates of the dicing lines DL3 and DLd and the intersection coordinates of the dicing lines DL4 and DLd. The location information of the skip line SL3 may be indicated by the intersection coordinates of the dicing lines DL4 and DLc and the intersection coordinates of the dicing lines DL4 and DLd. The location information of the skip line SL4 may be indicated by the intersection coordinates of the dicing lines DL4 and DLd and the intersection coordinates of the dicing lines DL5 and DLd. The location information of the skip line SL5 may be indicated by the intersection coordinates of the dicing lines DL4 and DLd and the intersection coordinates of the dicing lines DL4 and DLe.

Next, the control unit 30 controls the dicing unit 40 to skip the skip lines SL1 to SL5 among the dicing lines DL1 to DL5 and DLa to DLg and cut the other dicing lines. The dicing unit 40 cuts the dicing lines other than the skip lines SL1 to SL5 (S70), and the semiconductor chips CH that are divided into individual pieces are cut out from the semiconductor wafer W. Here, since the skip lines SL1 to SL5 are not cut, the adjacent semiconductor chips CHsk1 and CHsk2 remain connected, and the semiconductor chips CHsk3 to CHsk6 also remain connected. The semiconductor chips CHsk1, CHsk2, and CHsk3 to CHsk6 are not divided into individual pieces and are defective chips.

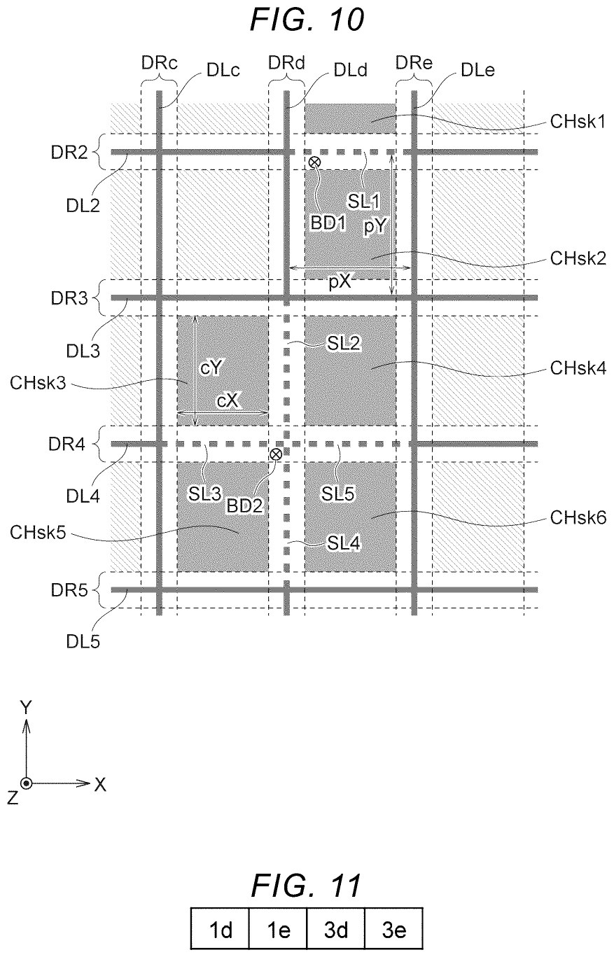

Next, the transmission unit 50 transmits the location information of the semiconductor chips CHsk1 and CHsk2 and the semiconductor chips CHsk3 to CHsk6 that are not divided into individual pieces to the outside (S80). FIG. 10 is a plan view showing the semiconductor chips CHsk1 to CHsk6 that are not divided into individual pieces. The location information of the semiconductor chips CHsk1 and CHsk2 and the semiconductor chips CHsk3 to CHsk6 that are not divided into individual pieces is location information of dicing lines surrounding the semiconductor chips CHsk1 and CHsk2 adjacent to the skip line SL1 and location information of dicing lines surrounding the semiconductor chips CHsk3 to CHsk6 adjacent to the skip lines SL2 to SL5.

For example, FIG. 11 is a table showing an example of location information of the dicing lines surrounding the semiconductor chips CHsk1 and CHsk2 that are not divided into individual pieces. The storage unit 70 stores location information of the dicing lines DL1 to DL5 and DLa to DLg and intersection coordinates of the dicing lines DL1 to DL5 and DLa to DLg. Therefore, the location information of the dicing lines surrounding the semiconductor chips CHsk1 and CHsk2 may be the coordinates of the corner portion of the dicing lines surrounding the semiconductor chips CHsk1 and CHsk2. For example, the semiconductor chips CHsk1 and CHsk2 are represented by an intersection coordinate 1d between the dicing lines DL1 and DLd, an intersection coordinate 1e between the dicing lines DL1 and DLe, an intersection coordinate 3d between the dicing lines DL3 and DLd, and an intersection coordinate 3e between the dicing lines DL3 and DLe.

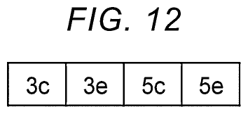

For example, FIG. 12 is a table showing an example of location information of the dicing lines surrounding the semiconductor chips CHsk3 to CHsk6 that are not divided into individual pieces. The location information of the dicing lines surrounding the semiconductor chips CHsk3 to CHsk6 may be coordinates of corner portions of the dicing lines surrounding the semiconductor chips CHsk3 to CHsk6. For example, the semiconductor chips CHsk3 to CHsk6 are represented by an intersection coordinate 3c between the dicing lines DL3 and DLc, the intersection coordinate 3e between the dicing lines DL3 and DLe, an intersection coordinate Sc between the dicing lines DL5 and DLc, and an intersection coordinate 5e between the dicing lines DL5 and DLe.

The transmission unit 50 may output the intersection coordinates shown in FIGS. 11 and 12 to the outside. Thereby, in a later assembly step, the semiconductor chips CHsk1 to CHsk6 in FIG. 10 may be prevented from being picked up. The information that the transmission unit 50 outputs to the outside is not the location information corresponding to the plurality of semiconductor chips CH, and may be the location information corresponding to one semiconductor chip CH. For example, when the skip line is set to a line segment of a dicing line corresponding to a side of the semiconductor chip CH on the outer peripheral side of the semiconductor wafer W on which the semiconductor chip CH is disposed at the outermost periphery of the semiconductor wafer W, instead of between the plurality of semiconductor chips CH adjacent to each other, one semiconductor chip CH adjacent to the center side of the semiconductor wafer W with respect to the skip line is not divided into individual pieces and is defective chip. Therefore, the location information of the dicing line surrounding the one semiconductor chip CH is output to the outside as the location information of the semiconductor chip CH that is not divided into individual pieces. That is, the transmission unit 50 transmits the location information of one or more semiconductor chips CH adjacent to the skip line to the outside as the location information of the semiconductor chips CH that are not divided into individual pieces.

According to the present embodiment, the calculation unit 20 automatically sets the dicing regions DR1 to DR5 and DRa to DRg based on the location information of the dicing lines DL1 to DL5 and DLa to DLg, the size information cX and cY of the semiconductor chip CH, and the interval information pX and pY of the dicing lines DL1 to DL5 and DLa to DLg. The calculation unit 20 sets a line segment between the semiconductor chips CHsk1 and CHsk2 adjacent to the defect BD1 among the dicing lines DL2 corresponding to the dicing region DR2 in which the defect BD1 is present, as the skip line SL1. In addition, the calculation unit 20 automatically sets the line segments between the semiconductor chips CHsk3 to CHsk6 adjacent to the defect BD2 among the dicing lines DL4 and DLd corresponding to the dicing regions DR4 and DRd in which the defect BD2 is present, as the skip lines SL2 to SL5. Thereby, the dicing unit 40 is capable of cutting the other line portions in the dicing lines DL1 to DL5 and DLa to DLg without cutting the portions of the skip lines SL1 and SL2 to SL5 having the defects BD1 and BD2.

As a result, it is possible to reduce the chipping of the semiconductor wafer W in the dicing step.

In addition, the skip line is set for each line segment of the dicing line corresponding to the side of the adjacent semiconductor chip CH. Therefore, the number of the semiconductor chips CHsk1 to CHsk6 that are not used as products may be reduced.

### Second Embodiment

A second embodiment will be described with reference to FIGS. 6 and 7.

In the second embodiment, the GUI 60 displays the defects BD1 and BD2, the dicing lines DL1 to DL5 and DLa to DLg, and the dicing regions DR1 to DR5 and DRa to DRg in the semiconductor wafer W as shown in FIG. 7. The GUI 60 may display a portion of the semiconductor wafer W in which the defects BD1 and BD2 are present as enlarged as shown in FIG. 7, or may display the entire semiconductor wafer W as shown in FIG. 6.

The user refers to the GUI 60 and selects the skip line based on the locations of the defects BD1 and BD2 and the dicing regions DR1 to DR5 and DRa to DRg. For example, the user selects and sets the skip lines SL1 and SL2 to SL5 for each line segment corresponding to the sides of the adjacent semiconductor chips CHsk1 to CHsk6 among the dicing lines DL2, DL4, and DLd corresponding to the dicing regions DR2, DR4, and DRd having the defects BD1 and BD2 in the dicing lines DL1 to DL5 and DLa to DLg. In this way, the user is able to select the skip line as appropriate while referring to the defects BD1 and BD2 and the dicing regions DR1 to DR5 and DRa to DRg by the GUI 60. Therefore, for example, the user is also able to remove the line segments (skip lines SL2 and SL5) in the dicing lines DL4 and DLd corresponding to the two sides of the semiconductor chip CHsk4 that are relatively far from the defect BD2, from the skip lines. The selection or the cancellation of the selection of the skip line may be executed by a user using an input function (for example, an input by a touch panel or an input by a keyboard) to the GUI 60.

Other configurations and operations of the second embodiment may be the same as the configurations and operations of the first embodiment. As a result, in the second embodiment, although the skip line is unable to be automatically set, the chipping of the semiconductor wafer W in the dicing step can be prevented as in the first embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor manufacturing apparatus comprising:
a storage device configured to store first location information of a plurality of first lines on a first surface of a semiconductor wafer to be cut, and further store second location information of a second line not to be cut among the plurality of first lines; and
a cutter configured to cut the semiconductor wafer along one or more of the plurality of first lines other than the second line;
wherein the semiconductor wafer is configured to be cut into a plurality of semiconductor chips.

2. The semiconductor manufacturing apparatus according to claim 1, wherein
the second line is configured for each line segment of each of the plurality of first lines corresponding to sides of the plurality of semiconductor chips, the plurality of first lines being adjacent to the plurality of semiconductor chips.

3. The semiconductor manufacturing apparatus according to claim 2, further comprising:
a receiver configured to receive third location information of a defect of the semiconductor wafer, wherein
the storage device is configured to further store the third location information and fourth location information of a first region to be removed by cutting between the plurality of semiconductor chips adjacent to each other, and store a line portion in the plurality of first lines corresponding to the first region having the defect as the second line.

4. The semiconductor manufacturing apparatus according to claim 3, wherein
the storage device is configured to further store product information including size information of the plurality of semiconductor chips and interval information between the plurality of first lines adjacent to each other for a plurality of products, and
the apparatus further comprises a calculator configured to set the first region based on the first location information, the size information, and the interval information.

5. The semiconductor manufacturing apparatus according to claim 4, wherein
the plurality of first lines include a plurality of first planned cutting lines extending in a first direction and a plurality of second planned cutting lines extending in a second direction intersecting the first direction, on the semiconductor wafer, and
the calculator is configured to set a region having a width of ±(pY−cY)/2 in the second direction from each of the plurality of first planned cutting lines and a region having a width of ±(pX−cX)/2 in the first direction from each of the plurality of second planned cutting lines as the first region,
where a width of the plurality of semiconductor chips in the first direction is represented by cX, a width of the plurality of semiconductor chips in the second direction is represented by cY, an interval between the plurality of second planned cutting lines adjacent to each other in the first direction is represented by pX, and an interval between the plurality of first planned cutting lines adjacent to each other in the second direction is represented by pY.

6. The semiconductor manufacturing apparatus according to claim 3, further comprising:
a calculator configured to set the second line in the plurality of first lines corresponding to the first region having the defect, based on the third location information and the fourth location information.

7. The semiconductor manufacturing apparatus according to claim 6, wherein
the calculator is further configured to set the second line for each line segment of each line corresponding to the sides of the plurality of semiconductor chips adjacent to each other in the plurality of first lines corresponding to the first region having the defect.

8. The semiconductor manufacturing apparatus according to claim 3, further comprising:
a display device that displays a location of the defect in the semiconductor wafer, the plurality of first lines, and the first region; and
an input device that allows a user to select the second line from the plurality of first lines based on the location of the defect and the first region.

9. The semiconductor manufacturing apparatus according to claim 1, further comprising:
a transmitter configured to transmit fifth location information of one or more semiconductor chips adjacent to the second line among the plurality of semiconductor chips.

10. The semiconductor manufacturing apparatus according to claim 9, wherein
the fifth location information includes location information of the plurality of first lines surrounding the one or more semiconductor chips adjacent to the second line.

11. The semiconductor manufacturing apparatus according to claim 1, wherein
the cutter includes a blade or a laser generator for cutting the semiconductor wafer into the plurality of semiconductor chips.

12. A method for manufacturing a semiconductor device, comprising:
cutting, by a cutter of a semiconductor manufacturing apparatus, a semiconductor wafer into a plurality of semiconductor chips along a plurality of first lines to be cut other than a second line which is a part of one of the plurality of first lines based on first location information of the plurality of first lines and second location information of the second line, wherein the first lines and the second line are present on a first surface of the semiconductor wafer.

13. The manufacturing method according to claim 12, wherein
the second line is configured for each line segment of each of the plurality of first lines corresponding to sides of the plurality of semiconductor chips, wherein the plurality of first lines are adjacent to the plurality of semiconductor chips.

14. The manufacturing method according to claim 13, wherein
the second line is set to the plurality of first lines corresponding to a first region having a defect of the semiconductor wafer based on third location information of the defect of the semiconductor wafer and fourth location information of the first region to be removed by cutting between the plurality of semiconductor chips adjacent to each other.

15. The manufacturing method according to claim 14, wherein
the semiconductor manufacturing apparatus further includes a calculator configured to set the first region, and
the method further comprises, before cutting the semiconductor wafer, setting the first region based on the first location information, size information of the plurality of semiconductor chips, and interval information between the plurality of first lines adjacent to each other, in the calculator.

16. The manufacturing method according to claim 15, wherein
the plurality of first lines include a plurality of first planned cutting lines extending in a first direction and a plurality of second planned cutting lines extending in a second direction intersecting the first direction, on the semiconductor wafer,
the calculator is configured to set a region having a width of ±(pY−cY)/2 in the second direction from each of the plurality of first planned cutting lines and a region having a width of ±(pX−cX)/2 in the first direction from each of the plurality of second planned cutting lines as the first region,
where a width of the plurality of semiconductor chips in the first direction is represented by cX, a width of the plurality of semiconductor chips in the second direction is represented by cY, an interval between the plurality of second planned cutting lines adjacent to each other in the first direction is represented by pX, and an interval between the plurality of first planned cutting lines adjacent to each other in the second direction is represented by pY.

17. The manufacturing method according to claim 14, wherein
the semiconductor manufacturing apparatus further includes a calculator configured to set the second line, and
the method further comprises, before cutting the semiconductor wafer, setting a line portion of the plurality of first lines corresponding to the first region having the defect as the second line, based on the third location information and the fourth location information, in the calculator.

18. The manufacturing method according to claim 17, wherein
the calculator is configured to set the second line for each line segment of each line corresponding to the sides of the plurality of semiconductor chips adjacent to each other in the plurality of first lines corresponding to the first region having the defect.

19. The manufacturing method according to claim 14, wherein
the semiconductor manufacturing apparatus further includes a display device and an input device, and
the method further comprises, before cutting the semiconductor wafer,
displaying a location of the defect in the semiconductor wafer, the plurality of first lines, and the first region on the display device, and
receiving the second line selected by a user from the plurality of first lines from the input device.

20. The manufacturing method according to claim 12, wherein
the semiconductor manufacturing apparatus further includes a transmitter, and
the method further comprises transmitting fifth location information of one or more semiconductor chips adjacent to the second line among the plurality of semiconductor chips.
